(19) United States
(12) Patent Application Publication
(10) Pub. No.: US 2026/0096325 A1
(43) Pub. Date: Apr. 2, 2026

(54) OLED DISPLAY PANEL AND DISPLAY DEVICE

(71) Applicant: SeeYA Optronics Co., Ltd., Shanghai (CN)

(72) Inventors: Chang-Ho Tseng, Shanghai (CN); Peng Yan, Shanghai (CN); Liyuan Luo, Shanghai (CN); Zhiyang Gao, Shanghai (CN)

(73) Assignee: SeeYA Optronics Co., Ltd., Shanghai (CN)

(21) Appl. No.: 19/216,028

(22) Filed: May 22, 2025

(30) Foreign Application Priority Data
Sep. 29, 2024 (CN) 202411377474.8

(51) Int. Cl. H10K 59/38; H10K 59/35; H10K 59/80; H10K 102/00

(52) U.S. Cl. CPC H10K 59/38; H10K 59/35; H10K 59/87; H10K 2102/351

(57) ABSTRACT

An OLED display panel, a preparation method thereof and a display device are provided. The OLED display panel includes a light-emitting layer and a light filter layer. The light filter layer includes a color filter film. The color filter film includes at least two of a red filter film, a green filter film and a blue filter film. At least two color filter films of different colors are alternately arranged in the light filter layer.

### CROSS-REFERENCE TO RELATED APPLICATION(S)

This application claims priority to Chinese Patent Application No. 202411377474.8, filed on Sept. 29, 2024, the disclosure of which is incorporated herein by reference in its entirety.

### TECHNICAL FIELD

This disclosure pertains to the field of display technology, and specifically relates to an OLED display panel, a preparation method of the OLED display panel, and a display device.

### BACKGROUND

Organic light-emitting display devices, namely organic light-emitting diodes (OLED), due to their thinness, power saving, and other characteristics, have many unparalleled advantages over liquid crystal displays and have become a research hotspot.

Color filters are key components for organic light-emitting display devices to achieve color display. Color filters are optical filters presenting colors that can accurately select a small range waveband of light waves to pass through, and reflect other undesirable light waves, thereby presenting different colors by the different light bands transmitted through different color sub-pixels, and presenting the desired color by controlling the light transmittance intensity of different color sub-pixels.

At present, color filters are generally installed on the light-emitting side of the display panel so that the human eye can receive saturated light of a certain color. The basic structure of a color filter includes a glass substrate, a black matrix, a color layer and a protective layer; the main function of the black matrix is to block stray light between sub-pixels, improve the color purity of the color filter, and expand the color gamut; however, the existing black matrix materials cannot have both low reflectivity and high optical concentration compatibly, and will also cause environmental pollution. Moreover, the existence of the black matrix will make the preparation process of the display panel more complicated.

Therefore, it is urgent to develop an OLED display panel having a technical solution that can replace the existing black matrix.

### SUMMARY

An OLED display panel and a preparation method thereof, as well as a display device are provided according to the present disclosure, where a material different from the black matrix is adopted for a light-shielding area in the OLED display panel, which solves the problems in the conventional technology.

According to one aspect of the present disclosure, an OLED display panel is provided, the OLED display panel includes a light-emitting layer and a light filter layer.

The light-emitting layer includes at least two of a red light-emitting unit, a blue light-emitting unit and a green light-emitting unit.

The light filter layer includes a color filter film.

The color filter film includes at least two of a red filter film, a green filter film and a blue filter film.

The color filter films of at least two different colors are alternately arranged in the light filter layer, and a blocking wall with a sandwich structure is provided between two adjacent color filter films of different colors, and the blocking wall is composed of the color filter films.

In a direction from the light filter layer to the light-emitting layer, the blocking wall includes an upper layer, a middle layer and a lower layer arranged in sequence.

A color of the upper layer is the same as the color of the lower layer and different from the color of the middle layer, and the color of the upper layer is different from the color of at least one of two adjacent color filter films of different colors on two sides of the blocking wall.

At least one of the upper layer and the lower layer is directly connected to one with the same color of the adjacent color filter films on two sides of the blocking wall, and the middle layer is directly connected to one with the same color of the adjacent color filter films on two sides of the blocking wall.

In the direction from the light filter layer to the light-emitting layer, a thickness of the middle layer is greater than the thickness of the upper layer and greater than the thickness of the lower layer.

In a direction from the color filter film on one side of the blocking wall to the color filter film on another side of the blocking wall, a width of the middle layer is the same as the width of the lower layer, and the same as or different from the width of the upper layer.

According to another aspect of the present disclosure, a preparation method of an OLED display panel is provided, which includes as follows.

A light-emitting layer is provided, where the light-emitting layer is a multi-film layer stacked structure at least including an OLED anode, an OLED light-emitting stacked composite film layer, a cathode, a thin film encapsulation layer, and a planarization layer; and
a light filter layer is formed on the light-emitting layer to obtain the OLED display panel.

According to another aspect of the present disclosure, a display device is provided, the display device includes the OLED display panel described above.

Compared with the conventional technology, the OLED display panel provided in the present disclosure is provided with a blocking wall with a sandwich structure between two adjacent color filter films of different colors. In one aspect, the blocking wall with a sandwich structure can achieve the effect of a black matrix, effectively block stray light between sub-pixels, thereby improving the color purity of RGB and expanding the color gamut; in another aspect, the blocking wall with a sandwich structure is defined to be composed of color filter films of two different colors, and the colors of the upper layer and lower layer are the same and are different from the color of the middle layer, and the color of the upper and lower layers is different from the color of at least one of the two adjacent color filter films of different colors on two sides of the blocking wall, and moreover, the thickness of the middle layer is greater than the thickness of each of the upper and lower layers, thereby effectively improving the problems of poor consistency of view angle light emission ratios of RGB three colors and increased view angle color shift of the conventional OLED display panel in the conventional filter overlapping technology, so that the obtained OLED display panel has higher luminous color purity. In addition, the sandwich-structured blocking wall can reduce the step between color filter films of different colors, thereby forming blocking walls with close heights at the adjacent side positions. The OLED display panel formed based on this has effectively improved consistency of the view angle light emission ratios of RGB three colors, solves the large view angle color shift problem of the conventional display panel and has an improved display effect.

It should be understood that the content described in this section is not intended to identify the key or important features of the embodiments of the present disclosure, nor is it intended to limit the scope of the present disclosure. Other features of the present disclosure will become easy to understand through the following description.

### BRIEF DESCRIPTION OF DRAWINGS

In order to more clearly illustrate the technical solutions in the embodiments of the present disclosure, the drawings required for the description of the embodiments are briefly introduced below. Obviously, the drawings described below are only some embodiments of the present disclosure. For the person of ordinary skills in the art, other drawings can be obtained based on these drawings without making creative efforts.

FIG. 1 is a schematic diagram of a conventional OLED display panel;

FIG. 2 is a simulation test diagram of tristimulus values of two OLED display panels;

FIG. 3 is a schematic diagram of an OLED display panel provided in an embodiment of the present disclosure;

FIG. 4 is a schematic diagram of another OLED display panel provided in an embodiment of the present disclosure;

FIG. 5 is a schematic diagram of still another OLED display panel provided in an embodiment of the present disclosure;

FIG. 6 is a schematic diagram of still another OLED display panel provided in an embodiment of the present disclosure;

FIG. 7 is a simulation test diagram of tristimulus values of the two OLED display panels in FIG. 1 and FIG. 3;

FIG. 8 is a schematic diagram of OLED display panels with blocking walls of different widths provided in embodiments of the present disclosure for comparison;

FIG. 9 is a schematic diagram of OLED display panels with blocking walls of different shapes provided in embodiments of the present disclosure for comparison;

FIG. 10 is a schematic diagram of another OLED display panel provided in an embodiment of the present disclosure;

FIG. 11 is a schematic diagram of another OLED display panel provided in an embodiment of the present disclosure;

FIG. 12 is a schematic diagram of another OLED display panel provided in an embodiment of the present disclosure;

FIG. 13 is a schematic diagram of another OLED display panel provided in an embodiment of the present disclosure;

FIG. 14 is a schematic diagram of another OLED display panel provided in an embodiment of the present disclosure;

FIG. 15 is a schematic diagram of another OLED display panel provided in an embodiment of the present disclosure; and FIG. 16 is a schematic diagram of a preparation method of an OLED display panel provided in an embodiment of the present disclosure.

### DETAILED DESCRIPTION

In order to enable the person skilled in the art to better understand the scheme of the present disclosure, the technical scheme in the embodiments of the present disclosure is clearly and completely described below in conjunction with the drawings in the embodiments of the present disclosure. Obviously, the described embodiments are only embodiments of a part of the present disclosure, not all embodiments. Based on the embodiments of the present disclosure, all other embodiments obtained by the person of ordinary skills in the art without creative work should fall within the scope of protection of the present disclosure.

It should be noted that the terms “first”, “second”, etc. in the specification and claims of the present disclosure and the above drawings are used to distinguish similar objects, and are not necessarily used to describe a specific order or sequence. It should be understood that the data used in this way can be interchangeable where appropriate, so that the embodiments of the present disclosure described here can be implemented in an order other than those illustrated or described here. In addition, the terms “including” and “having” and any variations thereof are intended to cover non-exclusive inclusions. For example, a process, method, system, product or device that includes a series of steps or units is not necessarily limited to those steps or units explicitly listed, but may include other steps or units that are not explicitly listed or inherent to the process, method, product or device.

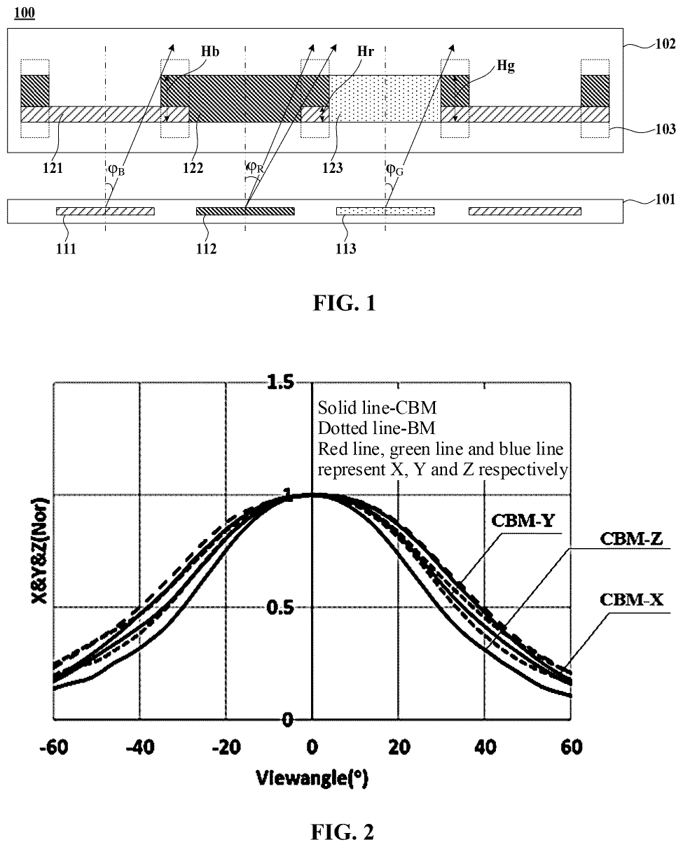

FIG. 1 is a schematic diagram of a conventional OLED display panel. In the cross-sectional structure of the OLED display panel 100 shown in FIG. 1, the OLED display panel 100 at least includes a light-emitting layer 101 and a light filter layer 102. The light-emitting layer 101 includes a blue light-emitting unit 111, a red light-emitting unit 112, and a green light-emitting unit 113. The light filter layer 102 is arranged corresponding to the light-emitting layer 101. Specifically, the light filter layer 102 includes a blue filter film 121, a red filter film 122, and a green filter film 123, and a light-shielding area 103 is provided between two adjacent filters of different colors. The light-shielding area 103 is formed by partially overlapping the blue filter film 121 and the red filter film 122. The formation of the light-shielding area 103 mentioned herein refers to selecting the same materials as the color filter films to form the light-shielding area 103. It can be understood that in other embodiments, the light-shielding area of the OLED display panel 100 can be formed by partially overlapping the blue filter film and the green filter film, or the light-shielding area of the OLED display panel 100 can be formed by partially overlapping the red filter film and the green filter film. In this embodiment, the light-shielding area 103 formed by partially overlapping the blue filter film 121 and the red filter film 122 is used as an example for explanation.

At the same large view angle, as shown in FIG. 1, among the blue light rays (B) emitted by the blue light-emitting unit 111, the blue light rays with emission angles less than or equal to φ_{B} will not be blocked by the light-shielding area 103 outside the blue filter film 121, so the small-angle blue light rays can pass through the blue filter film 121 and be directly emitted normally. However, among the blue light rays emitted by the blue light-emitting unit 111, most of the blue light rays with emission angles greater than φ_{B} are blocked by the red filter film 122 in the light-shielding area 103 outside the blue filter film 121, so these large-angle blue light rays are mostly absorbed by the light-shielding area 103 and cannot be emitted.

Similarly, as shown in FIG. 1, among the green light rays (G) emitted by the green light-emitting unit 113, the green light rays with emission angles less than or equal to φ_{G} can pass through the green filter film 123 and be emitted directly, while the green light rays with emission angles greater than φ_{G} are mostly absorbed by the red filter film 122 and the blue filter film 121 in the light-shielding area 103 outside the green filter film 123 and cannot be emitted.

As for the red light-emitting unit 112, as shown in FIG. 1, among the red light rays (R) emitted by the red light-emitting unit 112, most of the red light rays with emission angles less than or equal to φ_{R} can pass through the red filter film 122 and be emitted directly, and some of the red light rays will enter the red filter film 122 in the light-shielding area 103 outside the red filter film 122, but the red filter film 122 in the light-shielding area 103 will not block them. Therefore, the red light rays with emission angles less than or equal to φ_{R} of the red light-emitting unit 122 can basically be emitted normally, and most of the red light rays with emission angles greater than φ_{R} are absorbed by the blue filter film 121 in the light-shielding area 103 outside the red filter film 122 and cannot be emitted.

At the same large view angle, the emission angle φ_{B} of the blue light of the blue light-emitting unit 111 is approximately equal to the emission angle OG of the green light of the green light-emitting unit 113, and the emission angle OG of the green light of the green light-emitting unit 113 is smaller than the emission angle QR of the red light of the red light-emitting unit 122.

Obviously, at the same large view angle, the light emission angle φ_{R} of the red light-emitting unit 122 in the OLED display panel 100 is larger. Accordingly, overall amount of the red light rays emitted from the OLED display panel 100 is the largest, so that the difference between the red light emission amount and any one of the blue light emission amount and the green light emission amount in the OLED display panel 100 is large, and there is a problem that the consistency of the view angle light emission ratios of RGB three colors of the OLED display panel 100 is deteriorated, resulting in the problem that the picture color of the OLED display panel 100 is reddish at a large view angle.

In order to better verify the above problem, a simulation test was conducted on the tristimulus values of the conventional OLED display panel in FIG. 1 and a traditional OLED display panel, and the simulation test diagram of the tristimulus values obtained by the test is shown in FIG. 2. In the traditional OLED display panel, the traditional black matrix (BM) is used as a blocking wall between two adjacent filters of different colors. The light-shielding area 103 formed by the color filter film overlap technology is defined as CBM, and the CBM structure is used to replace the traditional black matrix (BM) structure. The tristimulus values are the expression of the degree of stimulation of the three primary colors that cause the human retina to perceive a certain color. The tristimulus values include an X value, a Y value and a Z value, where the X value represents red stimulation amount, the Y value represents green stimulation amount, and the Z value represents blue stimulation amount.

FIG. 2 is a simulation test diagram of the tristimulus values of two OLED display panels. In FIG. 2, the solid lines represent the tristimulus values of the OLED display panel 100 based on the CBM structure shown in FIG. 1, and the dotted lines represent the tristimulus values of the traditional OLED display panel based on the BM structure. In the coordinate system of FIG. 2, the horizontal axis represents the view angle (unit: °), and the vertical axis represents the stimulus value (unit: Nor).

In FIG. 2, the red solid line CBM-X represents the X value of the OLED display panel 100 based on the CBM structure shown in FIG. 1, the green solid line CBM-Y represents the Y value of the OLED display panel 100, and the blue solid line CBM-Z represents the Z value of the OLED display panel 100.

In FIG. 2, the red dotted line represents the X value of the traditional OLED display panel based on the BM structure, the green dotted line represents the Y value of the traditional OLED display panel, and the blue dotted line represents the Z value of the traditional OLED display panel.

It can be clearly seen from FIG. 2 that at a large view angle, such as −40° or +40°, the blue solid line CBM-Z, the red solid line CBM-X and the green solid line CBM-Y corresponding to the OLED display panel 100 have large differences therebetween, among which the red solid line CBM-X, i.e., the X value is the largest, and the blue solid line CBM-Z, i.e., the Z value is the smallest. Therefore, the simulation result of FIG. 2 is that as the view angle increases, the Z value of the OLED display panel 100 decreases rapidly, and the X value and the Z value gradually separate in terms of view angle.

The larger the stimulus value, the greater the contribution of the corresponding color component in visual matching. Therefore, in FIG. 2, the red solid line CBM-X, that is, the X value corresponding to the OLED display panel 100, is the largest, indicating that the red light (R) of the OLED display panel 100 contributes more to visual matching, and the corresponding OLED display panel 100 may have a problem of reddish picture color at a large view angle.

It can be seen from this that the conclusion drawn from the simulation test of the tristimulus values of FIG. 2 confirms the problem of reddish picture color at the large view angle of the structure of FIG. 1.

In fact, the problem of the above-mentioned OLED display panel 100 is a common problem of display panels in which two color filter films overlapped are used as blocking walls. Because after the two color filter films are overlapped to form a light-shielding area, it is inevitable that there will be a large step between the color filter films of different colors, and then blocking walls of different heights will be formed at adjacent side positions. As shown in FIG. 1, the side wall height (also referred to as thickness) of the blue filter film 121 corresponding to the blue light-emitting unit 111 is Hb, the side wall height of the red filter film 122 corresponding to the red light-emitting unit 112 is Hr, and the side wall height of the green filter film 123 corresponding to the green light-emitting unit 113 is Hg, Hb=Hg>Hr. In practice, Hb in the OLED display panel 100 is about 1.2 μm, and Hr is about 0.4 μm. The side walls are just the blocking walls at the adjacent side positions of the color filter films. Then, in the process of light passing through the color filter film, different colors of light will inevitably encounter different degrees of side wall effect, resulting in the poor consistency of the view angle light emission ratios of RGB three colors of the OLED display panel 100.

In order to solve the above-mentioned problems of the OLED display panel 100, a new type of OLED display panel is provided according to the present disclosure to solve the above-mentioned technical problems. The following is a detailed description of several specific structures of the OLED display panel provided by the present disclosure in conjunction with the accompanying drawings.

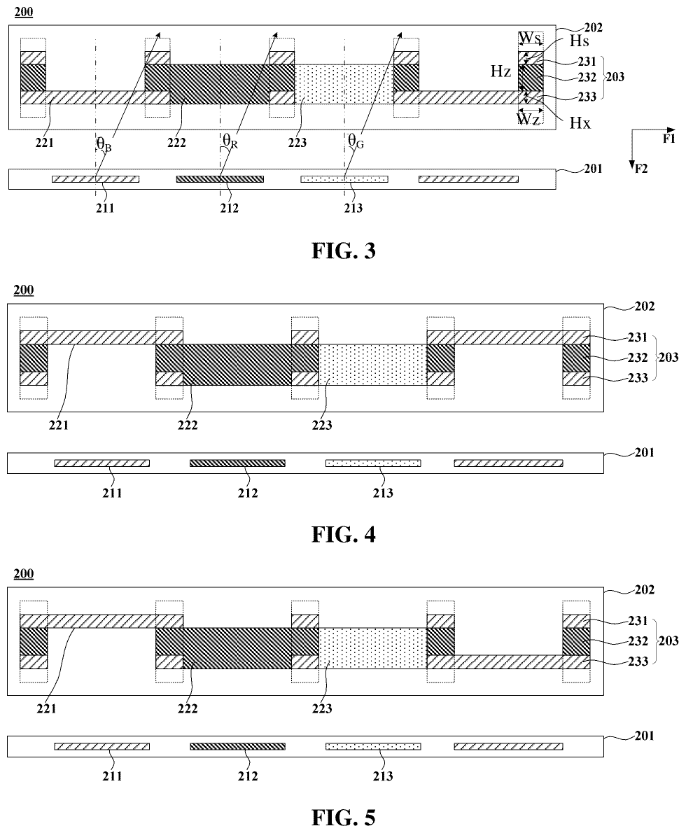

FIG. 3 is a schematic diagram of an OLED display panel provided in an embodiment of the present disclosure. The OLED display panel 200 shown in FIG. 3 is different from the OLED display panel 100 shown in FIG. 1.

In the cross-sectional structure of the OLED display panel 200 as shown in FIG. 3, the OLED display panel 200 at least includes a light-emitting layer 201 and a light filter layer 202. The light-emitting layer 201 includes at least two of a blue light-emitting unit 211, a red light-emitting unit 212 and a green light-emitting unit 213. The light filter layer 202 includes a color filter film. The color filter film includes at least two of a blue filter film 221, a red filter film 222 and a green filter film 223. At least two color filter films of different colors are alternately arranged in the light filter layer 202, a blocking wall 203 with a sandwich structure is provided between two adjacent color filter films of different colors, and the blocking wall 203 is composed of color filter films. In a direction from the light filter layer 202 to the light-emitting layer 201 (represented by an F2 direction in FIG. 3), the blocking wall 203 includes an upper layer 231, a middle layer 232 and a lower layer 233 arranged in sequence. The color of the upper layer 231 is the same as that of the lower layer 233, but is different from that of the middle layer 232, and the color of the upper layer 231 is different from the color of at least one of the two adjacent color filter films of different colors on two sides of the blocking wall 203. At least one of the upper layer 231 and the lower layer 233 is directly connected to one, with the same color as it, of adjacent color filter films on two sides of the blocking wall 203, and the middle layer 232 is directly connected to one, with the same color as it, of adjacent color filter films on two sides of the blocking wall 203. In the direction from the light filter layer 202 to the light-emitting layer 201, a thickness Hz of the middle layer 232 is greater than a thickness Hs of the upper layer 231, and the thickness Hz of the middle layer 232 is greater than a thickness Hx of the lower layer 233. In a direction from a color filter film on one side of the blocking wall 203 to a color filter film on the other side of the blocking wall 203 (represented by an F1 direction in FIG. 3), a width Wz of the middle layer 232 is the same as the width of the lower layer 233, and is the same as or different from a width Ws of the upper layer 231.

In this embodiment, the OLED display panel 200 includes a light-emitting layer 201. In one or more embodiments, the light-emitting layer 201 may include blue light-emitting units 211, red light-emitting units 212, and green light-emitting units 213, and the blue light-emitting units 211, the red light-emitting units 212, and the green light-emitting units 213 are alternately arranged in the light-emitting layer 201. In other embodiments, further, the light-emitting layer may include light-emitting units of two different colors, for example, the light-emitting layer includes red light-emitting units and green light-emitting units alternately arranged, but is not limited thereto.

The OLED display panel 200 includes a light filter layer 202 arranged corresponding to the light-emitting layer 201, and the light filter layer 202 is arranged on the light-emitting side of the light-emitting layer 201. In one or more embodiments, the light filter layer 202 may include blue filter films 221, red filter films 222, and green filter films 223 alternately arranged. The blue filter films 221, the red filter films 222, and the green filter films 223 are alternately arranged in the light filter layer 202. The blue light emitted by the blue light-emitting unit 211 is emitted through the blue filter film 221, the red light emitted by the red light-emitting unit 212 is emitted through the red filter film 222, and the green light emitted by the green light-emitting unit 213 is emitted through the green filter film 223. It can be understood that the light-emitting units in the light-emitting layer are arranged correspondingly to the color filter films in the light filter layer. For example, the light-emitting layer includes red light-emitting units and green light-emitting units arranged alternately. Correspondingly, the light filter layer includes red filter films arranged corresponding to the red light-emitting units and green filter films arranged corresponding to the green light-emitting units. Hereinafter, the red light of the OLED display panel 200 refers to the red light emitted by the red light-emitting units 212, the green light of the OLED display panel 200 refers to the green light emitted by the green light-emitting units 213, and the blue light of the OLED display panel 200 refers to the blue light emitted by the blue light-emitting units 211.

A blocking wall 203 having a sandwich structure is provided between two adjacent color filter films of different colors in the light filter layer 202, and the blocking wall 203 is composed of color filter films. In the direction from the light filter layer 202 to the light-emitting layer 201 (indicated by the F2 direction in FIG. 3), the blocking wall 203 includes an upper layer 231, a middle layer 232, and a lower layer 233 arranged in sequence. The upper layer 231 and the lower layer 233 have the same color, and the upper layer 231 and the middle layer 232 have different colors. In this embodiment, the blocking wall 203 is formed by partially overlapping a blue filter film 221 and a red filter film 222. The upper layer 231 and the lower layer 233 are both formed by using the blue filter film 221, and the middle layer 232 is formed by using the red filter film 222. However, the disclosure is not limited thereto, and other different structures will be described in subsequent embodiments, which will not be described in detail here. In this embodiment, the structure is described by taking the upper layer 231 as a blue filter film 221 and the middle layer 232 as a red filter film 222 as an example. The blocking wall 203 described herein is composed of color filter films, which means that the blocking wall 203 can be prepared using the same materials as the color filter films. Therefore, in this embodiment, either the upper layer 231 or the lower layer 233 can be formed using the same material as the blue filter film 221, and the middle layer 232 can be formed using the same material as the red filter film 222.

The color of the upper layer 231 is different from the color of at least one of the two adjacent color filter films of different colors on two sides of the blocking wall 203. In this embodiment, when the two adjacent color filter films are respectively a red filter film 222 and a green filter film 223, the color of the upper layer 231 of the blocking wall 203 between the two adjacent color filter films is different from the color of either of the two adjacent color filter films. When one of the two adjacent color filter films is a blue filter film 221, the color of the upper layer 231 of the blocking wall 203 between the two adjacent color filter films is the same as the color of the blue filter film 221 of the two adjacent color filter films.

At least one of the upper layer 231 and the lower layer 233 is directly connected to one, with the same color as it, of adjacent color filter films on two sides of the blocking wall 203, and the middle layer 232 is directly connected to one, with the same color as it, of adjacent color filter films on two sides of the blocking wall 203. In this embodiment, when one of the two adjacent color filter films is a red filter film 222, the color of the middle layer 232 of the blocking wall 203 between the two adjacent color filter films is the same as the color of the red filter film 222 of the two adjacent color filter films, then the middle layer 232 of the blocking wall 203 is directly connected to the adjacent red filter film 222 of the same color. Specifically, the same material as the red filter film 222 can be selected to form the middle layer 232, so that the red filter film 222 and the middle layer 232 can be directly manufactured through a single patterning process during preparation. When one of the two adjacent color filter films is a blue filter film 221, the lower layer 233 of the blocking wall 203 between the two adjacent color filter films is directly connected to the adjacent blue filter film 221 of the same color. Specifically, the lower layer 233 can be formed of the same material as the blue filter film 221. Therefore, the blue filter film 221 and the lower layer 233 can be directly manufactured through a single patterning process during preparation. In the present disclosure, the single patterning process refers to a process of forming the required layer structure through a single time of steps such as coating, exposure and development.

FIG. 4 is a schematic diagram of another OLED display panel provided in an embodiment of the present disclosure. The OLED display panel in FIG. 4 is different from that in FIG. 3 in that when one of the two adjacent color filter films in FIG. 4 is a blue filter film 221, the upper layer 231 of the blocking wall 203 between the two adjacent color filter films is directly connected to the adjacent blue filter film 221 of the same color.

FIG. 5 is a schematic diagram of another OLED display panel provided in an embodiment of the present disclosure. The OLED display panel in FIG. 5 is different from that in FIG. 3 in that when one of the two adjacent color filter films in FIG. 5 is a blue filter film 221, any one of the upper layer 231 and the lower layer 233 of the blocking wall 203 between the two adjacent color filter films is directly connected to the adjacent blue filter film 221 of the same color.

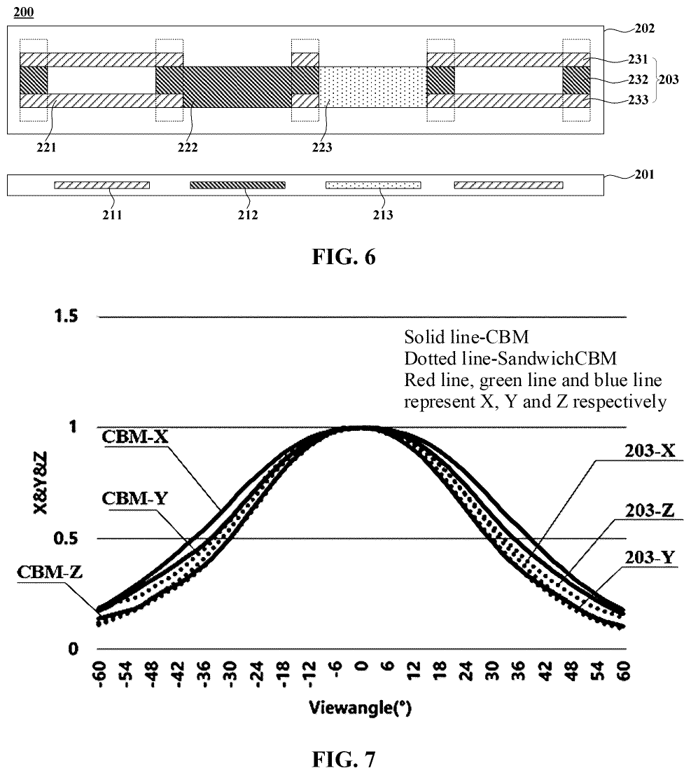

FIG. 6 is a schematic diagram of another OLED display panel provided in an embodiment of the present disclosure. The OLED display panel in FIG. 6 is different from that in FIG. 3 in that when one of the two adjacent color filter films in FIG. 6 is a blue filter film 221, the upper layer 231 of the blocking wall 203 between the two adjacent color filter films is directly connected to the adjacent blue filter film 221 of the same color, and also, the lower layer 233 of the blocking wall 203 is directly connected to the adjacent blue filter film 221 of the same color.

It can be understood that since the materials of the color filter films of different colors in the light filter layer 202 are different, the preparation processes of the color filter films of different colors are also different, during the preparation process, the thinnest color filter film can be preferentially formed in the light filter layer area directly above the opening corresponding the light-emitting unit, as the lower layer 233, and then the color filter film of any other color is formed as the middle layer 232, and then the upper layer 231 is formed. The upper layer 231 and the lower layer 233 of the blocking wall 203 are limited to the same color, which not only simplifies the preparation process, but also ensures that the overall thickness of the blocking wall 203 is not too high since only two colors of color filter films are used to form the blocking wall 203. If the thickness of the blocking wall 203 is too large, the blocking wall 203 will limit the view angle light output, reduce the view angle brightness, and the process is complicated, which will lead to a decrease in product yield.

Continuing to refer to FIG. 3, in the direction from the light filter layer 202 to the light-emitting layer 201, i.e., in the F2 direction, the thickness Hz of the middle layer 232 is greater than the thickness Hs of the upper layer 231, and the thickness Hz of the middle layer 232 is greater than the thickness Hx of the lower layer 233. In this embodiment, a thicker color filter film is used as the middle layer 232 of the blocking wall 203, and a thinner color filter film is used as the upper layer 231 and the lower layer 233 of the blocking wall 203, which is conducive to thinning the blocking wall 203 and reducing the height of the blocking wall 203, thereby can increase the emission angle of the light-emitting unit, and accordingly, can increase the light emission amount of the light-emitting unit.

In the direction from the color filter film on one side of the blocking wall 203 to the color filter film on the other side of the blocking wall 203 (indicated by the F1 direction in FIG. 3), the width Wz of the middle layer 232 is the same as the width of the lower layer 233, and the width Wz of the middle layer 232 is the same as or different from the width Ws of the upper layer 231. In this embodiment, Wz=Ws. However, it is not limited to this. In other embodiments, also, the width of the upper layer of the blocking wall can be different from the width of the middle layer.

At the same large view angle, as shown in FIG. 3, among the red light rays emitted by the red light-emitting unit 212, the red light rays with emission angles less than or equal to φ_{R} will not be blocked by the blocking wall 203 outside the red filter film 222, so these small-angle red light rays can pass through the red filter film 222 and be directly emitted normally. However, among the red light rays emitted by the red light-emitting unit 212, the red light rays with emission angles greater than φ_{R} will at least be blocked by the upper layer 231 of the blocking wall 203 outside the red filter film 222. Since the upper layer 231 is made of blue filter material, the blue upper layer 231 will block most of the red light rays so that they cannot be emitted. Therefore, these large-angle red light rays are mostly absorbed by the blocking wall 203 and cannot be emitted.

Similarly, as shown in FIG. 3, among the green light rays emitted by the green light-emitting unit 213, the green light rays with emission angles less than or equal to φ_{G} can pass through the green filter film 223 and be emitted directly, while the green light rays with emission angles greater than φ_{G} will mostly be absorbed by the blocking wall 203 outside the green filter film 223 and cannot be emitted.

As for the blue light-emitting unit 211, as shown in FIG. 3, among the blue light rays emitted by the blue light-emitting unit 211, most of the blue light rays with emission angles less than or equal to φ_{B} can pass through the blue filter film 221 and be emitted directly, and some of the blue light rays will be emitted into the upper layer 231 in the blocking wall 203 outside the blue filter film 221, but the blue upper layer 231 in the blocking wall 203 will not block the blue light rays. Therefore, the blue light rays with emission angles less than or equal to φ_{B} of the blue light-emitting unit 211 can basically be emitted normally, and most of the blue light rays with emission angles greater than φ_{B} are absorbed by the middle layer 232 in the blocking wall 203 outside the blue filter film 221 and cannot be emitted.

At the same large view angle, the emission angle φ_{G} of the green light of the green light-emitting unit 213 is approximately equal to the emission angle φ_{R} of the red light of the red light-emitting unit 212, and the emission angle φ_{B} of the blue light of the blue light-emitting unit 211 is greater than the emission angle φ_{R} of the red light of the red light-emitting unit 212.

Obviously, at the same large view angle, the light emission angle φ_{R} of the red light-emitting unit 212 in the OLED display panel 200 is approximately equal to the emission angle θ_{G} of the green light of the green light-emitting unit 213, so that the view angle light emission ratios of R and G colors of the OLED display panel 200 tends to be consistent, and the consistency of view angle light emission ratios of R and G colors of the OLED display panel 200 is improved.

At the same large view angle, the emission angle φ_{R} of the red light of the red light-emitting unit 212 in the OLED display panel 200 is less than the emission angle φ_{B} of the blue light of the blue light-emitting unit 211, so that the view angle light emission ratio of the B blue color of the OLED display panel 200 is improved.

In FIG. 2, for the OLED display panel 100 in which two layers of color filter films are used as the light-shielding area 103, the Z value decreases rapidly, and the Z value is less than the X value. The X value and the Z value gradually separate and contrast in the view angle, and the difference between the two is large.

In this embodiment, the view angle light emission ratios of the R and G colors of the OLED display panel 200 tend to be consistent, and the view angle light emission ratio of the B blue color of the OLED display panel 200 is increased, thereby reducing the view angle light emission ratio difference between R color and B color in the OLED display panel 200, making the view angle light emission ratios of RGB three colors tend to be consistent, thereby improving the consistency of the view angle light emission ratios of RGB three colors of the OLED display panel 200, mitigating the problem of reddish picture color of the OLED display panel 200 at a large view angle, and reducing the view angle color shift. It effectively solves the problem of inconsistent light emission ratios at different view angles and increased view angle color shift of the OLED display panel 100 shown in FIG. 1.

In order to further illustrate that the OLED display panel 200 according to the present disclosure can improve the consistency of the view angle light emission ratios of RGB three colors and reduce the view angle color shift, the tristimulus values of the OLED display panel 200 shown in FIG. 3 is simulated and tested, and the simulation test diagram of the obtained tristimulus values is as shown in FIG. 7.

FIG. 7 is a simulation test diagram of the tristimulus values of the two OLED display panels in FIG. 1 and FIG. 3. In FIG. 7, the solid lines represent the tristimulus values of the OLED display panel 100 shown in FIG. 1, and the dotted lines represent the tristimulus values of the OLED display panel 200 shown in FIG. 3.

It can be clearly seen from FIG. 7 that at a large view angle, such as −60° or +60°, the blue dotted line 203-Z, the red dotted line 203-X and the green dotted line 203-Y corresponding to the OLED display panel 200 have a small difference between them, while the blue solid line CBM-Z, the red solid line CBM-X and the green solid line CBM-Y corresponding to the OLED display panel 100 have a large difference between them. By comparison, it can be seen that the difference between the X value corresponding to the red dotted line 203-X in the OLED display panel 200 and the Z value corresponding to the blue dotted line 203-Z in the OLED display panel 200 is reduced, and the Z value corresponding to the blue dotted line 203-Z is greater than the Z value corresponding to the blue solid line CBM-Z in the OLED display panel 100. Therefore, it can be seen from FIG. 7 that the OLED display panel 200 has a reduced red light output, an increased blue light output, and a reduced difference between the red light output and blue light output. Therefore, the consistency of the view angle light emission ratios of RGB three colors of the OLED display panel 200 is better than that of the OLED display panel 100, which mitigates the problem of the reddish picture color of the OLED display panel 100 at a large view angle, and the OLED display panel 200 can reduce the view angle color shift.

Therefore, the conclusion drawn from the simulation test of the tristimulus values of FIG. 7 confirms that the structure shown in FIG. 3 is better than the structure shown in FIG. 1, solves the problem of the reddish picture color at the large view angle, and improves the consistency of the light emission ratios of RGB three colors.

In fact, in the OLED display panel 200 described above, two kinds of color filter films are overlapped to form a sandwich-structured blocking wall 203. The thickness of the upper layer 231 is relatively small, so the step between the color filter films of different colors can be reduced, thereby forming blocking walls 203 with similar heights at the adjacent side positions.

In the OLED display panel 100 in FIG. 1, the side wall height of the blue filter film 121 corresponding to the blue light-emitting unit 111 is about 1.2 μm, and the side wall height of the red filter film 122 corresponding to the red light-emitting unit 112 is about 0.4 μm. The side wall height difference of the two color filter films of different colors is about 0.8 μm.

Referring to FIG. 3, the side wall height (also referred to as thickness) of the blue filter film 221 corresponding to the blue light-emitting unit 211 is Hz+Hx, the side wall height of the red filter film 222 corresponding to the red light-emitting unit 212 and the side wall height of the green filter film 223 corresponding to the green light-emitting unit 213 are both Hs+Hz+Hx, and the thickness Hs of the upper layer 231 is relatively small. In one or more embodiments, in the OLED display panel 200, Hz+Hx is approximately 1.2 μm, and Hs is approximately 0.4 μm. Obviously, the side wall height difference between the blue filter film 221 and the red filter film 222 is approximately 0.4 μm. Compared with FIG. 1, the step between the color filter films of different colors of the OLED display panel 200 in FIG. 3 is effectively reduced. Thus, in the process of light passing through the color filter film, the side wall effect degrees encountered by light of different colors tend to be relatively close, thereby improving the consistency of the view angle light emission ratios of RGB three colors of the OLED display panel 200, and further mitigating the view angle color shift problem.

It should be noted that, in this embodiment, the thickness, width and other parameters of each layer in the blocking wall 203 are not fixed values, nor are there specific requirements imposed on them. They can be adjusted according to practical product requirements.

In one or more embodiments, the red filter material includes phthalocyanine red and/or azo red; the green filter material includes phthalocyanine green and/or azo green; the blue filter material includes any one or a combination of at least two of aluminum phthalocyanine, phthalocyanine blue and azo blue.

Compared with the conventional technology, the OLED display panel provided in the present disclosure is provided with a blocking wall with a sandwich structure between two adjacent color filter films of different colors. In one aspect, the blocking wall with a sandwich structure can achieve the effect of a black matrix, effectively block stray light between sub-pixels, thereby improving the color purity of RGB and expanding the color gamut; in another aspect, the blocking wall with a sandwich structure is defined to be composed of color filter films of two different colors, the colors of the upper layer and lower layer are the same and are different from the color of the middle layer, and the color of the upper and lower layers is different from the color of at least one of the two adjacent color filters of different colors on two sides of the blocking wall, and moreover, the thickness of the middle layer is greater than the thickness of each of the upper and lower layers, thereby effectively improving the problems of poor consistency of view angle light emission ratios of RGB three colors and increased view angle color shift of the conventional OLED display panel in the conventional filter overlapping technology, so that the obtained OLED display panel has higher luminous color purity. In addition, the sandwich-structured blocking wall can reduce the step between color filter films of different colors, thereby forming blocking walls with close heights at the adjacent side positions. The OLED display panel formed based on this has effectively improved consistency of the view angle light emission ratios of RGB three colors, solves the large view angle color shift problem of the conventional display panel and has an improved display effect.

In one or more embodiments, in the blocking wall, it is assumed that the width of the upper layer is D, and the thickness of the middle layer is Hz, then D≥0.894×Hz. In order to make the light emission consistency of the OLED display panel better, the width of the upper layer of the blocking wall may be defined.

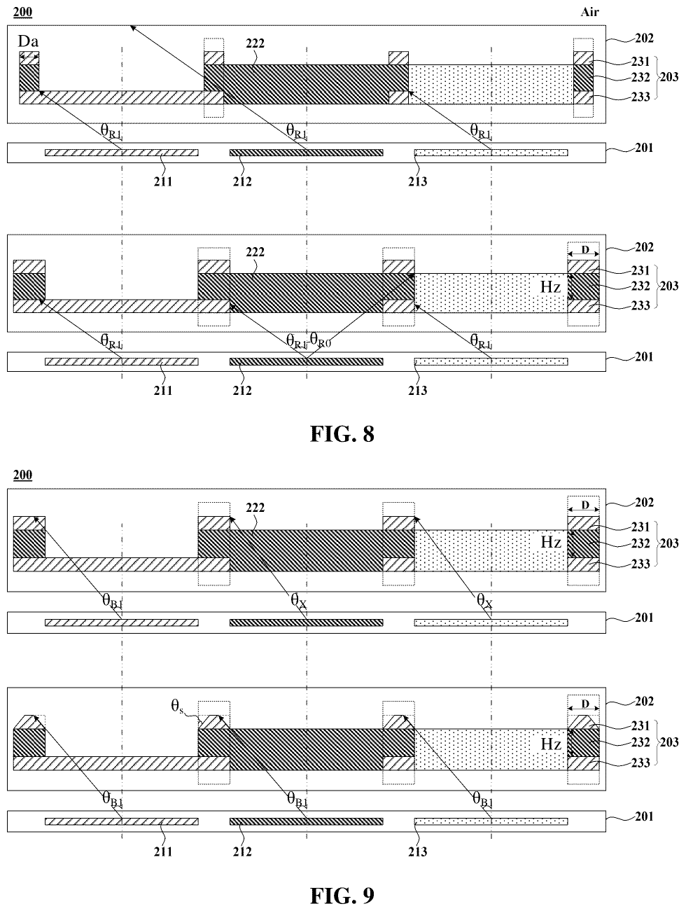

FIG. 8 is a schematic diagram of OLED display panels with blocking walls of different widths provided in embodiments of the present disclosure for comparison. As shown in FIG. 8, the thickness of the middle layer 232 of the blocking wall 203 is relatively large. If the width of the blocking wall 203 is too small, the blocking wall 203 may have a small effect on the light with a color different from that of the middle layer 232, but a large effect on the light with the same color as that of the middle layer 232.

In this embodiment, the color of the middle layer 232 of the blocking wall 203 is the same as the color of the red filter film 222. Based on this, if the width of the blocking wall 203 is too small (for example, the width is Da), then at the same large view angle θ_{R1}, the red light with the large view angle θ_{R1} may be emitted from the middle layer 232 of the blocking wall 203, while the blue light and green light with the large view angle θ_{R1} will not be emitted from the blocking wall 203, causing the OLED display panel 200 to have a problem of reddish picture color at a large view angle. Increasing the width of the blocking wall 203 can solve the problem of color shift at a large view angle in some degree. For example, if the width of the blocking wall 203 is increased to D, then at the same large view angle θ_{R1}, none of the red light, green light and blue light of the large view angle θ_{R1} will be emitted from the blocking wall 203, thereby improving the problem of color shift at a large view angle of the OLED display panel 200.

The width D of the blocking wall 203 will be specifically analyzed below. Here, the width of the upper layer 231 of the blocking wall 203 is assumed to be D, where D is the width of a side of the upper layer 231 facing the middle layer 232.

In the F1 direction, the width of the upper layer 231 is D, and in the F2 direction, the thickness of the middle layer 232 of the blocking wall 203 is Hz, and tan θ_{R0}=D/Hz. Most of the light rays with emission angles less than θ_{R0} can be emitted from the area defined by the blocking wall 203, while the light rays with emission angles greater than or equal to θ_{R0} are completely blocked by the blocking wall 203 and cannot be emitted from the blocking wall 203. For example, θ_{R1} is greater than θ_{R0}. The blue light ray with the large view angle θ_{R1} is blocked by the middle layer 232 of the blocking wall 203 and cannot be emitted, and the green light ray and red light ray with the large view angle ORI are each blocked by the lower layer 233 of the blocking wall 203 and cannot be emitted.

When the light rays are incident from a denser medium (a medium with a large refractive index) into a sparser medium (a medium with a small refractive index), and when the incident angle increases to a certain angle to allow the refraction angle to reach 90°, the incident angle corresponding to this case is just the total reflection critical angle. When an incident angle is greater than the total reflection critical angle, the light ray at this incident angle will no longer enter the light-sparse medium, but will be completely reflected back to the light-dense medium. In the OLED display panel 200, the side of the light filter layer 202 facing away from the light-emitting layer 201 is the air medium Air, the refractive index of air is 1, and the refractive index of the light filter layer 202 is greater than 1, so the light filter layer 202 is a light-dense medium, and the air medium Air is a light-sparse medium.

It is assumed that the total reflection critical angle of the red light emitted by the red light-emitting unit 212 is θ_{R2}. It can be understood that the red light rays emitted by the red light-emitting unit 212 with emission angles less than or equal to θ_{R2} will not be totally reflected, and most of them can be emitted from the light filter layer 202 to the air medium Air. The red light rays emitted by the red light-emitting unit 212 with emission angles greater than θ_{R2} will be subjected to total reflection since their incident angles are greater than the total reflection critical angle θ_{R2}, so that the red light rays with emission angles greater than θ_{R2} cannot be emitted from the light filter layer 202 to the air medium Air, but are totally reflected back into the light filter layer 202. The red light rays with emission angles greater than θ_{R2} are reflected back into the light filter layer 202 by the light-emitting side of the light filter layer 202, which will interfere with other color light rays.

In order to avoid interference between light rays, it is necessary to use a blocking wall 203 to block the red light rays with emission angles greater than θ_{R2} to prevent the red light rays with emission angles greater than θ_{R2} from being incident on the light-emitting side of the light filter layer 202 and being totally reflected.

θ_{R0} is designed to be greater than θ_{R2}.

It is known that most of the light rays with emission angles less than θ_{R0} can be emitted from the area defined by the blocking wall 203, while the light rays with emission angles greater than or equal to θ_{R0} are totally blocked by the blocking wall 203 and cannot be emitted from the blocking wall 203. If the minimum value of θ_{R0} is equal to θ_{R2}, most of the light rays with emission angles less than θ_{R2} can be emitted from the area defined by the blocking wall 203, while the light rays with emission angles greater than or equal to θ_{R2} will be blocked by the blocking wall 203 and cannot be emitted from the blocking wall 203.

Therefore, by designing θ_{R0} to be greater than θ_{R2}, the blocking wall 203 can effectively block the red light rays with emission angles greater than the total reflection critical angle θ_{R2}, thereby preventing the red light rays with large view angles greater than the total reflection critical angle θ_{R2} from being incident on the light-emitting side of the light filter layer 202 and being totally reflected.

The refractive index of the material of the color filter film is generally greater than 1.5. According to the law of refraction, the total reflection critical angle θ_{R2} of red light meets θ_{R2}<41.8°. Specifically, it can be obtained according to the law of refraction that, sin θ_{R2}/sin θₐᵢᵣ=1/nᵣ, where θ_{R2} is the incident angle of red light, θₐᵢᵣ is the refraction angle of a light ray entering the air from the light filter layer 202, 1 is the refractive index of air, and nᵣ is the refractive index of the red filter film 222. Since θ_{R2} is the total reflection critical angle of red light, θₐᵢᵣ is 90°, then sin θₐᵢᵣ=1, and the refractive index nr of the red filter film 222 meets nᵣ>1.5, then sin θ_{R2}=1/nᵣ<1/1.5 can be obtained, and it is calculated to obtain θ_{R2}<41.8°.

θ_{R0} is greater than θ_{R2}, θ_{R2}<41.8°. The minimum value of ORO can be designed as 41.8°.

When the minimum value of θ_{R0} is 41.8°, it means that only red light rays with emission angles less than 41.8° can be emitted from the area defined by the blocking wall 203, while red light rays with emission angles greater than or equal to 41.8°°will be totally blocked by the blocking wall 203 and cannot be emitted from the blocking wall 203. Therefore, the minimum value of θ_{R0} can be designed to be 41.8°, so that the blocking wall 203 can block the red light rays with emission angles greater than θ_{R2} from being emitted.

D/Hz=tan θ_{R0}≥tan 41.8°=0.894, that is, D≥0.894×Hz. Thus, the blocking wall 203 can block the red light rays with emission angles greater than θ_{R2}, so that they cannot be emitted from the blocking wall 203.

According to the above relationship, the minimum value of the width D of the upper layer 231 of the blocking wall 203 is 0.894×Hz, which can effectively avoid the problem of light ray emission at a larger view angle due to the insufficient width of the upper layer 231 of the blocking wall 203, avoid the total reflection phenomenon, and reduce the interference between sub-pixels.

In one or more embodiments, the cross-sectional shape of the upper layer can be a regular trapezoid; it is assumed that the angle between the light ray emitted from the side close to the upper layer and the direction perpendicular to the light filter layer is θ_{B1}, and the angle between the hypotenuse of the regular trapezoid and the direction perpendicular to the light filter layer is θ_{S}, then θ_{S}>θ_{B1}; θ_{S}<41.8°.

FIG. 9 is a schematic diagram of OLED display panels with blocking walls of different shapes provided in embodiments of the present disclosure for comparison. As shown in FIG. 9, the upper layer 231 of the blocking wall 203 can be designed as a regular trapezoid, which can improve the consistency of the light emission ratios of RGB three colors at the same view angle. In one or more embodiments, the cross-sectional shape of the upper layer 231 can be a regular trapezoid; and it is assumed that the angle between the light emitted from the side close to the upper layer 231 and the direction perpendicular to the light filter layer 202 is θ_{B1}, and the angle between the hypotenuse of the regular trapezoid and the direction perpendicular to the light filter layer 202 is θ_{S}, then θ_{S}>θ_{B1}; and θ_{S}<41.8°.

As shown in FIG. 9, the color of the upper layer 231 of the blocking wall 203 is blue, so the blue light rays emitted by the blue light-emitting unit 211 with angles less than or equal to θ_{B1} can be emitted smoothly. However, if the cross-sectional shape of the upper layer 231 of the blocking wall 203 is a rectangle, neither the red light nor the green light with the same emission angle θ_{B1} can be emitted. Specifically, the red light rays emitted by the red light-emitting unit 212 with angles less than or equal to θ_{X} can be emitted smoothly, and the green light rays emitted by the green light-emitting unit 213 with angles less than or equal to θ_{X} can be emitted smoothly, and θ_{X} is less than θ_{B1}. As a result, at the angle θ_{B1}, the red light and green light emitted from the entire OLED display panel 200 are relatively small, and the blue light is relatively large, which will also cause the problem of increased view angle color shift. The blue light emission ratio is higher than the red light emission ratio and green light emission ratio, which causes the problem of inconsistent light emission ratios of RGB three colors in the OLED display panel 200.

In order to solve this problem, the cross-sectional shape of the upper layer 231 of the blocking wall 203 is further defined as a regular trapezoid, and it is assumed that the angle between the hypotenuse of the regular trapezoid and the direction perpendicular to the filter layer 203 is θ_{S}, in order to restricting the light rays at large view angles greater than the angle θ_{S} from being emitted through the upper layer 231 of the blocking wall 203, θ_{S} is designed to meet θ_{S}≥θ_{B1} and θ_{S}<41.8°.

If the emission angle of red light is equal to the emission angle of green light, and the emission angle of green light is equal to the emission angle of blue light, the consistency of the light emission ratios of RGB three colors in the OLED display panel 200 can be improved. Based on this, the shape of the upper layer 231 of the blocking wall 203 can be designed as a regular trapezoid, and the angle between the hypotenuse of the regular trapezoid and the direction perpendicular to the light filter layer 202 is θ_{S}. θ_{S} is greater than or equal to θ_{B1}.

For the case where the upper layer 231 of the blocking wall 203 is a regular trapezoid, θ_{S} is greater than or equal to θ_{B1}, so that at the same emission angle θ_{B1}, the blue light emitted by the blue light-emitting unit 211 can be smoothly emitted, the red light emitted by the red light-emitting unit 212 can be smoothly emitted, the green light emitted by the green light-emitting unit 213 can be smoothly emitted, and θ_{B1} is greater than θ_{X}. Obviously, in the OLED display panel 200, the light emission ratios of blue light, green light and red light are close, which improves the consistency of the light emission ratios of RGB three colors.

If θ_{S} is greater than or equal to 41.8°, since 41.8° is greater than the total reflection critical angle of red light, the large view angle red light rays with emission angles equal to or greater than 41.8° may not be blocked by the upper layer 231 of the blocking wall 203, resulting in total reflection and interference with other sub-pixels. If θ_{S} is defined to less than 41.8°, the red light rays with emission angles exceeding 41.8° will be blocked by the upper layer 231 of the regular trapezoid and will not be emitted to the light-emitting side of the filter layer 203.

In one or more embodiments, a transparent filling layer is further provided in a groove formed between two adjacent blocking walls. In one or more embodiments, the material of the transparent filling layer includes an inorganic transparent material which is any one or a combination of at least two of transparent silicon nitride, transparent silicon oxide, and transparent silicon oxynitride; or, the material of the transparent filling layer includes an organic transparent material which is any one or a combination of at least two of transparent epoxy resin, transparent acrylate, transparent phenolic resin, and transparent polysiloxane resin; or, the material of the transparent filling layer includes a filter material of the same color as the color filter film in contact, and the filter material includes any one or a combination of at least two of squaric acid, phthalocyanine, perylene amide, and azo-type organic dyes. The material of the optional transparent filling layer includes a filter material of the same color as the color filter film in contact, and the concentration of the filter material in the transparent filling layer is lower than the concentration of the filter material in the color filter film in contact.

In one or more embodiments, in the groove formed between two adjacent blocking walls, the color filter film is located between the transparent filling layer and the light-emitting layer.

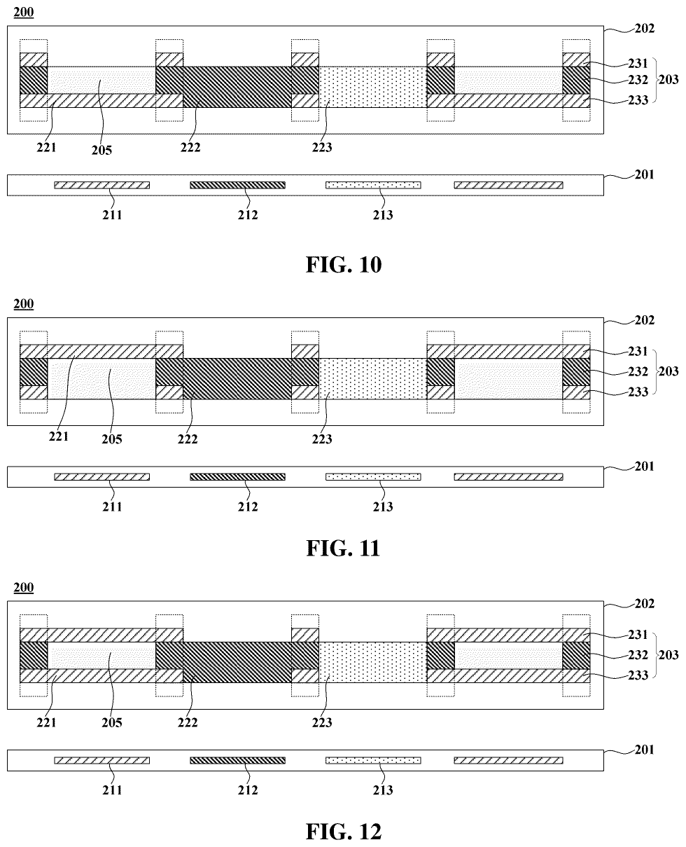

FIG. 10 is a schematic diagram of another OLED display panel provided in an embodiment of the present disclosure. Further, in order to ensure that the flatness of the prepared OLED display panel 200 is higher and the preparation is more convenient, as shown in FIG. 10, a transparent filling layer 205 may further be provided in a concave part at one side of the blocking walls 203. Specifically, the blue filter film 221 is directly connected to the lower layer 233 and has a relatively small thickness. The transparent filling layer 205 is provided on the blue filter film 221, that is, the blue filter film 221 is located between the transparent filling layer 205 and the light-emitting layer 201. In this way, the light-emitting side of the concave part between the blocking walls 203 corresponding to the blue light-emitting unit 211, the light-emitting side of the red filter film 222 corresponding to the red light-emitting unit 212, and the light-emitting side of the green filter film 223 corresponding to the green light-emitting unit 213 can be substantially flush.

In one or more embodiments, the transparent filling layer is located between the color filter film and the light-emitting layer in the groove formed between two adjacent blocking walls.

FIG. 11 is a schematic diagram of another OLED display panel provided in an embodiment of the present disclosure. Further, in order to ensure that the flatness of the prepared OLED display panel 200 is higher and the preparation is more convenient, as shown in FIG. 11, a transparent filling layer 205 may further be provided in the concave part at one side of the blocking walls 203. Specifically, the blue filter film 221 is directly connected to the upper layer 231. In order to prevent the blue filter film 221 from collapsing, the transparent filling layer 205 is first provided in the concave part between the blocking walls 203 corresponding to the blue light-emitting unit 211, and then the blue filter film 221 is provided on the transparent filling layer 205, that is, the transparent filling layer 205 is located between the blue filter film 221 and the light-emitting layer 201. In this way, the light-emitting side of the concave part between the blocking walls 203 corresponding to the blue light-emitting unit 211, the light-emitting side of the red filter film 222 corresponding to the red light-emitting unit 212, and the light-emitting side of the green filter film 223 corresponding to the green light-emitting unit 213 can be substantially flush.

In one or more embodiments, in the groove formed between two adjacent blocking walls, two color filter films of the same color arranged at an interval are included. In one or more embodiments, in the groove formed between two adjacent blocking walls, the color of the color filter film is the same as the color of the upper layer, and the upper layer is directly connected to the color filter film and/or the lower layer is directly connected to the color filter film. Referring to FIG. 6, in the groove formed between two adjacent blocking walls 203 corresponding to the blue light-emitting unit 211, two blue filter films 221 of the same color arranged at an interval are included, the blue filter film 221 of the same layer as the upper layer 231 is directly connected to the upper layer 231, and the blue filter film 221 of the same layer as the lower layer 233 is directly connected to the lower layer 233.

In one or more embodiments, a transparent filling layer is provided between the two color filter films of the same color in the groove formed between two adjacent blocking walls.

FIG. 12 is a schematic diagram of another OLED display panel provided in an embodiment of the present disclosure. Further, in order to ensure that the flatness of the prepared OLED display panel 200 is higher and the preparation is more convenient, as shown in FIG. 12, a transparent filling layer 205 may further be provided in the concave part at one side of the blocking walls 203. Specifically, in the groove formed between two adjacent blocking walls 203 corresponding to the blue light-emitting unit 211, two blue filter films 221 of the same color arranged at an interval are included. In order to prevent the blue filter film 221 from collapsing, a transparent filling layer 205 is provided between the two blue filter films 221 of the same color arranged at an interval. In this way, the light-emitting side of the concave part between the blocking walls 203 corresponding to the blue light-emitting unit 211, the light-emitting side of the red filter film 222 corresponding to the red light-emitting unit 212, and the light-emitting side of the green filter film 223 corresponding to the green light-emitting unit 213 can be substantially flush.

The material of the transparent filling layer 205 can be an inorganic transparent material or an organic transparent material.

The material of the transparent filling layer 205 may further be a filter material. As shown in FIG. 10, the transparent filling layer 205 is disposed on the blue filter film 221, and the material of the transparent filling layer 205 may further be a blue filter material. The concentration of the blue filter material in the transparent filling layer 205 can be lower than the concentration of the blue filter material in the blue filter film 221 in contact with it, so that the light transmittance of the transparent filling layer 205 can be improved.

In one or more embodiments, the organic transparent material includes any one or a combination of at least two of transparent epoxy resin, transparent acrylate, transparent phenolic resin or transparent polysiloxane resin. In one or more embodiments, the inorganic transparent material includes any one or a combination of at least two of transparent silicon nitride, transparent silicon oxide or transparent silicon oxynitride. In one or more embodiments, the filter material having the same color as the lower layer of the blocking wall includes any one or a combination of at least two of squaric acid, phthalocyanine, perylene amide or azo organic dyes.

Furthermore, the present disclosure has no special requirements on the materials of the red filter film 222, the green filter film 223 and the blue filter film 221, and simply conventional materials in the art may just be used. Illustratively, the material of the red filter film 222 includes phthalocyanine red and/or azo red, etc. ; illustratively, the material of the green filter film 223 includes phthalocyanine green and/or azo green; illustratively, the material of the blue filter film 221 includes any one or a combination of at least two of aluminum phthalocyanine, phthalocyanine blue or azo blue.

In fact, for the OLED display panel 200 provided in the embodiment of the present disclosure, there is no special restriction on the arrangement of the three different colors of the color filter films in the light filter layer 202, as long as the three different colors can be alternately distributed. Similarly, there is no special restriction on the colors of the upper layer 231, the middle layer 232 and the lower layer 233 in the sandwich-structured blocking wall 203, as long as the colors of the upper layer 231 and the lower layer 233 of the blocking wall 203 are the same, but different from the color of the middle layer 232, and the color of the middle layer 232 is the same as the color of the color filter film on either adjacent side, the problem of inconsistent light emission ratios and increased view angle color shift in the conventional OLED display panel 100 provided in FIG. 1 can be effectively solved.

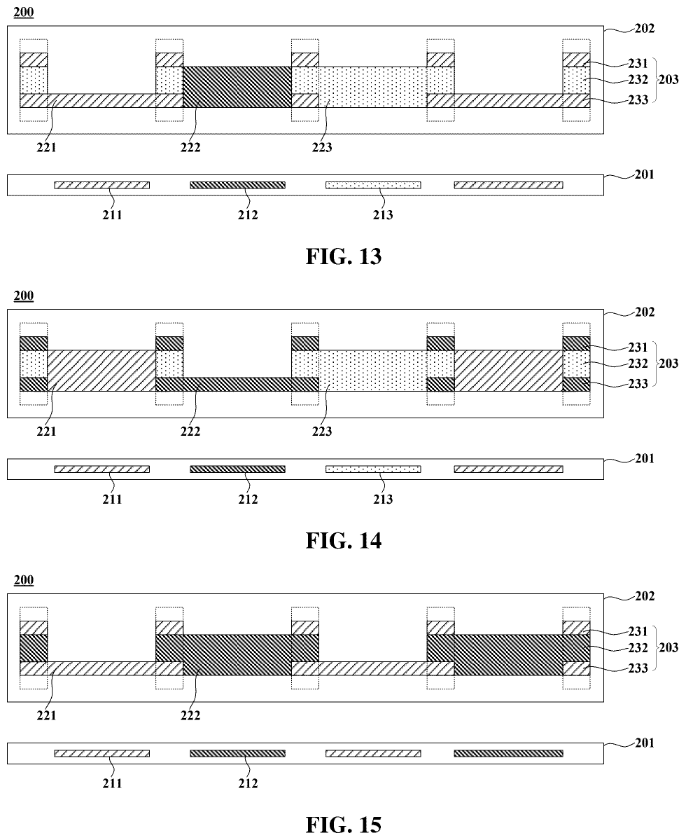

FIG. 13 is a schematic diagram of another OLED display panel provided in an embodiment of the present disclosure. For example, in the OLED display panel 200 shown in FIG. 13, the color of the upper layer 231 and the color of the lower layer 233 of the blocking wall 203 are both blue, and the color of the middle layer 232 is green. For the green filter film 223, it can be directly connected to the middle layer 232 in the adjacent blocking walls 203. For the blue filter film 221, it can be directly connected to the upper layer 231 or the lower layer 233 in the adjacent blocking walls 203.

FIG. 14 is a schematic diagram of another OLED display panel provided in an embodiment of the present disclosure. For example, in the OLED display panel 200 shown in FIG. 14, the upper layer 231 and the lower layer 233 of the blocking wall 203 are both red, and the color of the middle layer 232 is green. For the green filter film 223, it can be directly connected to the middle layer 232 in the adjacent blocking walls 203. For the red filter film 222, it can be directly connected to the upper layer 231 or the lower layer 233 in the adjacent blocking walls 203.

Other similar structures are within the scope of protection of the present disclosure and are not described here.

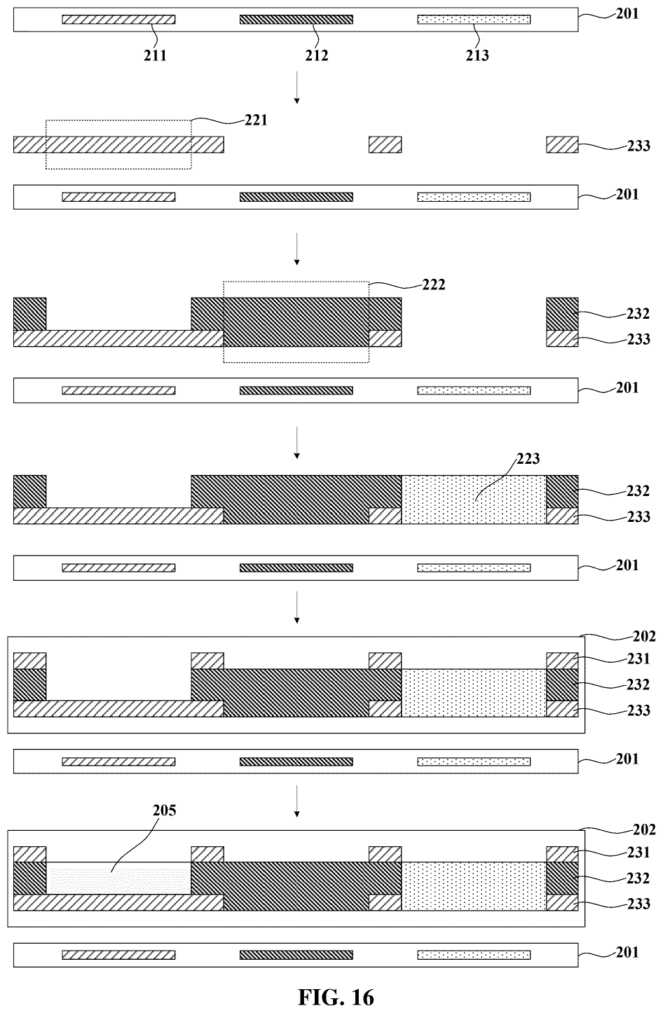

Even, according to practical requirements, the light filter layer 202 in the OLED display panel provided in the present disclosure may only include two colors of color filter films, as shown in FIG. 15. FIG. 15 is a schematic diagram of another OLED display panel provided in an embodiment of the present disclosure. For example, in the OLED display panel 200 shown in FIG. 15, the light filter layer 202 includes a red filter film 222 and a blue filter film 221. The upper layer 231 and the lower layer 233 of the blocking wall 203 are both blue, and the color of the middle layer 232 is red. For the red filter film 222, it can be directly connected to the middle layer 232 in the adjacent blocking walls 203. For the blue filter film 221, it can be directly connected to the upper layer 231 or the lower layer 233 in the adjacent blocking walls 203.

A preparation method of an OLED display panel is further provided according to an embodiment of the present disclosure, which can be used to prepare the OLED display panel described in any of the above embodiments. In this embodiment, the preparation method of the OLED display panel includes: providing a light-emitting layer, the light-emitting layer is a multi-film layer stacked structure, at least including an OLED anode, an OLED light-emitting stacked composite film layer, a cathode, a thin film encapsulation layer and a planarization layer; and forming a light filter layer on the light-emitting layer to obtain an OLED display panel.

Here, the overall process flow is described by taking the OLED display panel 200 shown in FIG. 3 as an example.

FIG. 16 is a schematic diagram of a preparation method of an OLED display panel provided in an embodiment of the present disclosure. As shown in FIG. 16, the method specifically includes the steps as follows.
(1) A substrate is provided, and sequentially the OLED anode, the OLED light-emitting stacked composite film layer, the cathode, the thin film encapsulation layer and the planarization layer are formed on the substrate as the light-emitting layer 201. The light-emitting layer 201 includes a first light-emitting area corresponding to a blue light-emitting unit 211, a second light-emitting area corresponding to a red light-emitting unit 212 and a third light-emitting area corresponding to a green light-emitting unit 213.
(2) A first light filter area is formed on the light-emitting layer 201 by coating, exposing and developing. The first light filter area includes two patterns, one of which is a pattern corresponding to the position of a lower layer 233 of a blocking wall, and the other is a pattern corresponding to the position of a blue light-emitting unit 211 in a first light-emitting area (this pattern is just the blue filter film 221).
(3) A second light filter area is formed by coating, exposing and developing. The second light filter area includes two patterns, one of which is a pattern corresponding to the position of a middle layer 232 of the blocking wall, and the other is a pattern corresponding to the position of a red light-emitting unit 212 in a second light-emitting area (the pattern is just the red filter film 222).
(4) A third light filter area is formed by coating, exposing and developing, the third light filter area is a pattern corresponding to the position of a green light-emitting unit 213 in a third light-emitting area (the pattern is just the green filter film 223).
(5) A fourth light filter area is formed by coating, exposing and developing, the fourth light filter area is a pattern corresponding to the position of an upper layer 231 of the blocking wall, thereby forming a light filter layer 202, and obtaining the OLED display panel.

Further, the method further includes: forming a transparent filling layer by coating to eliminate the step between different light-emitting areas. As shown in FIG. 16, the blue filter film 221 and the red filter film 222 form a step, and a transparent filling layer 205 can be formed on the blue filter film 221 to reduce the step between the first light-emitting area corresponding to the blue light-emitting unit 211, the second light-emitting area corresponding to the red light-emitting unit 212, and the third light-emitting area corresponding to the green light-emitting unit 213.

The transparent filling layer 205 can be formed after the third light filter area is formed. Alternatively, the transparent filling layer 205 can be formed after the fourth light filter area is formed, which is not specifically limited.

It can be seen from the above content that the color filter films in the light filter layer in the preparation method can be prepared by stacking them in sequence from the side close to the light-emitting layer.

A display apparatus is further provided according to embodiments of the present disclosure, which includes an OLED display panel as described in any of the above embodiments. The display device can be a display device such as an OLED display and any product or component with a display function such as a TV, a digital camera, a mobile phone, a tablet computer, etc. that includes these display devices.

It should be noted that the structure of the OLED display panel has been described in detail in the above embodiments, and thus will not be described here in detail.

The applicant declares that an OLED display panel and its preparation method and application are illustrated through the above embodiments in the present disclosure, but the present disclosure is not limited to the above structures and process steps, that is, it does not mean that the present disclosure must rely on the above process steps to be implemented. The person skilled in the art should understand that any improvement to the present disclosure, equivalent replacement of the raw materials selected by the present disclosure, addition of auxiliary components, selection of specific methods, etc., all fall within the scope of protection and disclosure of the present disclosure.

What is claimed is:

1. An OLED display panel, comprising a light-emitting layer and a light filter layer; wherein, the light-emitting layer comprises at least two of a red light-emitting unit, a blue light-emitting unit and a green light-emitting unit;
the light filter layer comprises a color filter film;
the color filter film comprises at least two of a red filter film, a green filter film and a blue filter film;
the color filter films of at least two different colors are alternately arranged in the light filter layer, a blocking wall with a sandwich structure is provided between two adjacent color filter films of different colors, and the blocking wall is composed of the color filter films;
in a direction from the light filter layer to the light-emitting layer, the blocking wall comprises an upper layer, a middle layer and a lower layer arranged in sequence;
a color of the upper layer is same as a color of the lower layer and different from a color of the middle layer, and the color of the upper layer is different from a color of at least one of two adjacent color filter films of different colors on two sides of the blocking wall;
at least one of the upper layer and the lower layer is directly connected to one with the same color of the adjacent color filter films on two sides of the blocking wall, and the middle layer is directly connected to one with the same color of the adjacent color filter films on two sides of the blocking wall;
in the direction from the light filter layer to the light-emitting layer, a thickness of the middle is greater than a thickness of the upper layer and greater than a thickness of the lower layer; and
in a direction from a color filter film on one side of the blocking wall to a color filter on another side of the blocking wall, a width of the middle layer is same as a width of the lower layer and same as or different from a width of the upper layer.

2. The OLED display panel according to claim 1, wherein the light filter layer comprises red filter films, green filter films and blue filter films arranged alternately.

3. The OLED display panel according to claim 1, wherein, if in the blocking wall, the width of the upper layer is D, the thickness of the middle layer is Hz, and D≥0.894×Hz.

4. The OLED display panel according to claim 1, wherein a cross-sectional shape of the upper layer is a regular trapezoid;
an angle between a light ray emitted from a side close to the upper layer and a direction perpendicular to the light filter layer is θ_{B1}, an angle between a hypotenuse of the regular trapezoid and the direction perpendicular to the light filter layer is θ_{S}, and θ_{S}>θ_{B1}; and θ_{S}<41.8°.

5. The OLED display panel according to claim 1, wherein a material of the red filter film comprises at least one of phthalocyanine red or azo red;
a material of the green filter film comprises at least one of phthalocyanine green or azo green; and
a material of the blue filter film comprises at least one of aluminum phthalocyanine, phthalocyanine blue or azo blue.

6. The OLED display panel according to claim 1, wherein a transparent filling layer is further provided in a groove formed between two adjacent blocking walls.

7. The OLED display panel according to claim 6, wherein in the groove formed between two adjacent blocking walls, the color filter film is located between the transparent filling layer and the light-emitting layer.

8. The OLED display panel according to claim 6, wherein in the groove formed between two adjacent blocking walls, the transparent filling layer is located between the color filter film and the light-emitting layer.

9. The OLED display panel according to claim 1, wherein in the groove formed between two adjacent blocking walls, two color filter films of the same color are arranged to be spaced apart.

10. The OLED display panel according to claim 9, wherein in the groove formed between two adjacent blocking walls, a color of the color filter film is same as the color of the upper layer, and at least one of the following is satisfied:
the upper layer is directly connected to the color filter film or the lower layer is directly connected to the color filter film.

11. The OLED display panel according to claim 9, wherein in the groove formed between two adjacent blocking walls, a transparent filling layer is arranged between the two color filter films of the same color.

12. The OLED display panel according to claim 6, wherein a material of the transparent filling layer comprises an inorganic transparent material, and the inorganic transparent material is at least one of transparent silicon nitride, transparent silicon oxide or transparent silicon oxynitride;
or, a material of the transparent filling layer comprises an organic transparent material, and the organic transparent material is at least one of transparent epoxy resin, transparent acrylate, transparent phenolic resin or transparent polysiloxane resin;
or, a material of the transparent filling layer comprises a filter material of the same color as the color filter film in contact, and the filter material comprises at least one of squaric acid, phthalocyanine, perylene amide or azo-type organic dyes.

13. The OLED display panel according to claim 12, wherein the material of the transparent filling layer comprises a filter material of the same color as the color filter film in contact, and a concentration of the filter material in the transparent filling layer is lower than a concentration of a filter material in the color filter film in contact.

14. The OLED display panel according to claim 11, wherein a material of the transparent filling layer comprises an inorganic transparent material, and the inorganic transparent material is at least one of transparent silicon nitride, transparent silicon oxide or transparent silicon oxynitride;
or, a material of the transparent filling layer comprises an organic transparent material, and the organic transparent material is at least one of transparent epoxy resin, transparent acrylate, transparent phenolic resin or transparent polysiloxane resin;
or, a material of the transparent filling layer comprises a filter material of the same color as the color filter film in contact, and the filter material comprises at least one of squaric acid, phthalocyanine, perylene amide or azo-type organic dyes.

15. A display device, comprising the OLED display panel according to claim 1.
